(19) United States
(12) Patent Application Publication
(10) Pub. No.: US 2026/0037707 A1
(43) Pub. Date: Feb. 5, 2026

(54) DATA PROCESSING DEVICE, DATA PROCESSING METHOD, AND COMPUTER READABLE MEDIUM

(71) Applicant: Mitsubishi Electric Corporation, Tokyo (JP)

(72) Inventors: Susumu HIRANO, Tokyo (JP); Yuichiro MURACHI, Tokyo (JP); Kosei SUZUKI, Tokyo (JP)

(73) Assignee: Mitsubishi Electric Corporation, Tokyo (JP)

(21) Appl. No.: 19/352,817

(22) Filed: Oct. 8, 2025

Related U.S. Application Data
(63) Continuation of application No. PCT/JP2024/000146, filed on Jan. 9, 2024.

(51) Int. Cl. G06F 30/3323; G06F 30/327

(52) U.S. Cl. CPC G06F 30/3323; G06F 30/327

(57) ABSTRACT

A formal verification executing unit performs a static analysis of at least either of RTL data and a net list of a semiconductor integrated circuit having two or more storage elements connected thereto and operating based on a clock cycle, extracts, from the two or more storage elements, a storage element with a shortest time being equal to or more than two clock cycles among times in which no signal transition occurs as a transition pause storage element, and extracts, from the two or more storage elements, a storage element of a connection source of the transition pause storage element as a connection-source storage element. Also, the formal verification executing unit determines to set a multicycle path between the transition pause storage element and the connection-source storage element.

### TECHNICAL FIELD

The present disclosure relates to a technology for setting a multicycle path in a semiconductor integrated circuit.

### BACKGROUND ART

In a semiconductor integrated circuit, a signal makes a transition by one clock cycle between two storage elements in general. On the other hand, for facilitation of the layout of the semiconductor integrated circuit, a multicycle path may be set in a semiconductor integrated circuit.

The multicycle path is a path in which a signal transition between two storage elements may be performed by two or more clock cycles. Setting the multicycle path in the semiconductor integrated circuit facilitates the design of the semiconductor integrated circuit. Also, setting the multicycle path in the semiconductor integrated circuit shortens a process time, reduces the circuit size, and reduces power consumption.

### CITATION LIST

### Patent Literature

Patent Literature 1: JP 5645754

### SUMMARY OF INVENTION

### Technical Problem

An object of the technology of Patent Literature 1 is to detect a multicycle path. In the technology of Patent Literature 1, logic verification using a verification pattern used in a RTL (Register Transfer Level) simulation is performed. Also, in the technology of Patent Literature 1, a signal transition is found with complex operation based on the result of logic verification, and multicycle path is set.

In the technology of Patent Literature 1, logic verification using a verification pattern is required. For this reason, the technology of Patent Literature 1 has a problem in which when a verification pattern is insufficient, sufficient logic verification cannot be performed and a multicycle path cannot be accurately set.

Also, in Patent Literature 1, a signal transition is found with complex operation based on the result of logic verification. For this reason, the technology of Patent Literature 1 has a problem of a heavy work load.

One of main objects of the present disclosure is to solve the problems as described above. More specifically, a main object of the present disclosure is to allow a multicycle path to be accurately set without using a verification pattern and putting a load on the designer of a semiconductor integrated circuit.

### Solution to Problem

A data processing device according to the present disclosure includes:
an analyzing and extracting unit to perform a static analysis of at least either of RTL (Register Transfer Level) data and a net list of a semiconductor integrated circuit having two or more storage elements connected thereto and operating based on a clock cycle, to extract, from the two or more storage elements, a storage element with a shortest time being equal to or more than two clock cycles among times in which no signal transition occurs as a transition pause storage element, and to extract, from the two or more storage elements, a storage element of a connection source of the transition pause storage element as a connection-source storage element; and
a multicycle path determining unit to determine to set a multicycle path between the transition pause storage element and the connection-source storage element.

### Advantageous Effects of Invention

According to the present disclosure, a multicycle path can be accurately set without using a verification pattern and putting a load on the designer of the semiconductor integrated circuit.

### BRIEF DESCRIPTION OF DRAWINGS

FIG. 1 is a diagram depicting part of a semiconductor integrated circuit according to Embodiment 1.

FIG. 2 is a timing waveform diagram corresponding to the circuit structure of FIG. 1.

FIG. 3 is a diagram depicting an example of hardware structure of a multicycle path setting device according to Embodiment 1.

FIG. 4 is a diagram depicting an example of functional structure of the multicycle path setting device according to Embodiment 1.

FIG. 5 is a flowchart depicting an example of operation of the multicycle path setting device according to Embodiment 1.

FIG. 6 is a diagram depicting an example of RTL data according to Embodiment 1.

FIG. 7 is a diagram depicting an example of property according to Embodiment 1.

FIG. 8 is a diagram depicting an example of a multicycle path constraint according to Embodiment 1.

FIG. 9 is a diagram depicting an example of functional structure of a multicycle path setting device according to Embodiment 2.

FIG. 10 is a diagram depicting an example of property according to Embodiment 2.

FIG. 11 is a flowchart depicting an example of operation of the multicycle path setting device according to Embodiment 2.

FIG. 12 is a diagram depicting a relation between analysis result information and updated analysis result information according to Embodiment 2.

FIG. 13 is a diagram depicting an example of updated analysis result information according to Embodiment 2.

FIG. 14 is a diagram depicting an example of unified analysis result information according to Embodiment 2.

FIG. 15 is a diagram depicting an example of a multicycle path constraint according to Embodiment 2.

FIG. 16 is a diagram depicting an example of functional structure of a multicycle path setting device according to Embodiment 3.

FIG. 17 is a flowchart depicting an example of operation of the multicycle path setting device according to Embodiment 3.

FIG. 18 is a diagram depicting an example of operation of an enable signal generating unit and a clock gating description adding unit according to Embodiment 3.

FIG. 19 is a diagram depicting an example of functional structure of a multicycle path setting device according to Embodiment 4.

FIG. 20 is a flowchart depicting an example of operation of the multicycle path setting device according to Embodiment 4.

### DESCRIPTION OF EMBODIMENTS

In the following, embodiments are described by using the drawings. In the following description of the embodiments and the drawings, those provided with the same reference character represent the same portion or corresponding portion.

### Embodiment 1

### General Outline

A general outline of the present embodiment is described.

In the present embodiment, a multicycle path setting device 100 described below acquires RTL data or a net list of a semiconductor integrated circuit.

The semiconductor integrated circuit according to the present embodiment has two or more storage elements connected thereto, and operates based on a clock cycle.

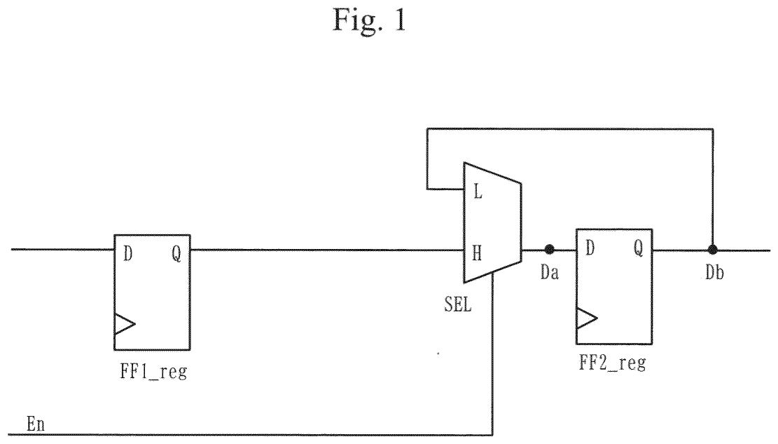

FIG. 1 depicts part of the semiconductor integrated circuit according to the present embodiment. The circuit structure depicted in FIG. 1 is assumed to be described in the RTL data.

In FIG. 1, FF1_reg and FF2_reg are connected via a selector. Note that “FF” means “Flip-Flop”. In place of FF or in addition to FF, a RAM (Random Access Memory) may be included in the semiconductor integrated circuit. In the following, unless otherwise noted, it is assumed that only FFs are included in the semiconductor integrated circuit. FF and RAM are examples of storage elements.

Also, in FIG. 1, Da is an input signal to FF2_reg. Db is an output signal from FF2_reg.

The multicycle path setting device 100 performs a static analysis of the RTL data or net list. The multicycle path setting device 100 performs, as static analysis, verification of specifications by a formal verification scheme, for example. Details of the formal verification scheme are described further below.

Then, the multicycle path setting device 100 extracts a storage element with a shortest transition pause time being equal to or more than two clock cycles as a transition pause storage element. A period in which no signal transition occurs is referred to as a transition pause time. Also, the multicycle path setting device 100 extracts a storage element of a connection source of the transition pause storage element as a connection-source storage element.

In the circuit structure of FIG. 1, the multicycle path setting device 100 extracts a FF with a shortest transition pause time being equal to or more than two clock cycles as a transition pause FF. Also, the multicycle path setting device 100 extracts a FF of a connection source of the transition pause FF as a connection-source FF.

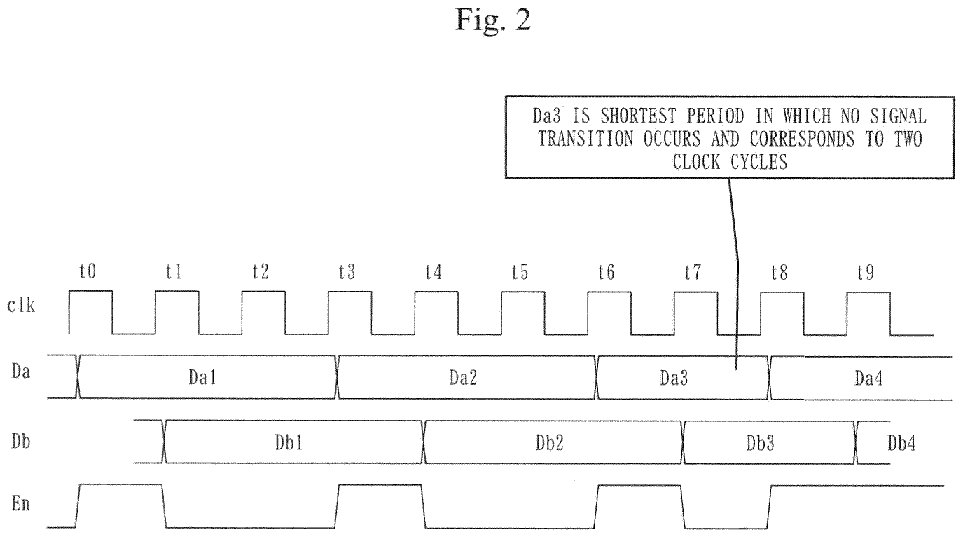

FIG. 2 is a timing waveform diagram of the circuit structure of FIG. 1.

In FIG. 2, “clk” represents a clock signal. “Da” represents a signal transition of the input signal Da. “Db” represents a signal transition of the output signal Db. “En” represents an enable signal.

A signal transition occurs from “Da1” to “Da2”, from “Da2” to “Da3”, and from “Da3” to “Da4” each. No signal transition occurs during “Da1”, during “Da2”, during “Da3”, and during “Da4” each. The same goes for the output signal Db.

In an example of FIG. 2, a shortest transition pause time, that is, a shortest time among periods in which no signal transition occurs, is “Da3”. “Da3” corresponds to two clock cycles. Thus, the multicycle path setting device 100 extracts FF2_reg as a transition pause FF. Also, the multicycle path setting device 100 extracts FF1_reg, which is a connection source of FF2_reg, as a connection-source FF.

Next, the multicycle path setting device 100 determines to set a multicycle path between the transition pause FF and the connection-source FF. In the example of FIG. 1 and FIG. 2, the multicycle path setting device 100 determines to set a multicycle path corresponding to two clock cycles between FF1_reg and FF2_reg.

Also, the multicycle path setting device 100 generates a multicycle path constraint for setting a multicycle path between FF1_reg and FF2_reg.

Then, the multicycle path setting device 100 adds the multicycle path constraint to a timing constraint file.

With this, the multicycle path setting device 100 accurately sets a multicycle path in the semiconductor integrated circuit without using a verification pattern and putting a load on the designer.

### Description of Structure

Next, an example of structure of the multicycle path setting device 100 according to the present embodiment is described.

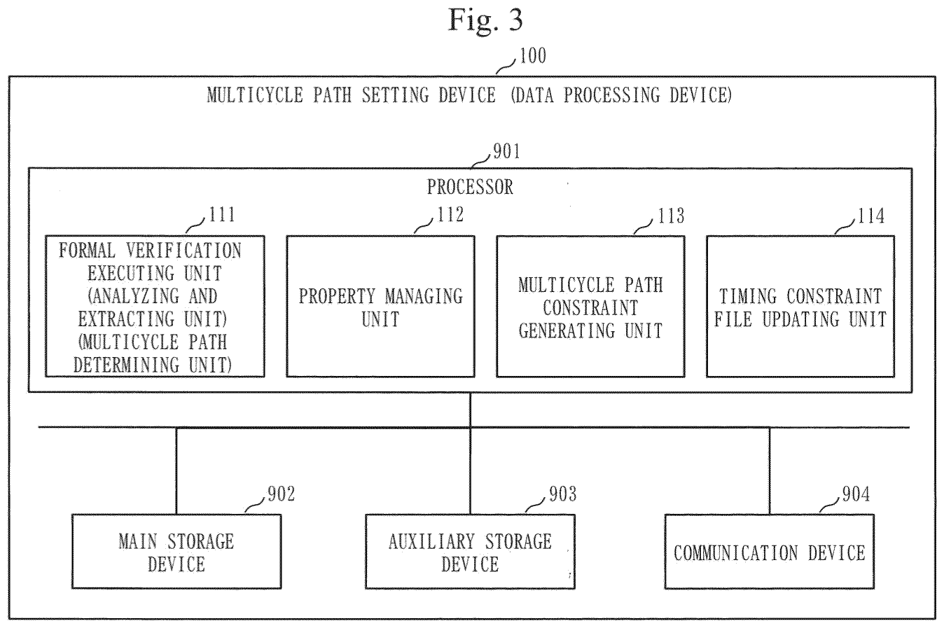

FIG. 3 depicts an example of hardware structure of the multicycle path setting device 100.

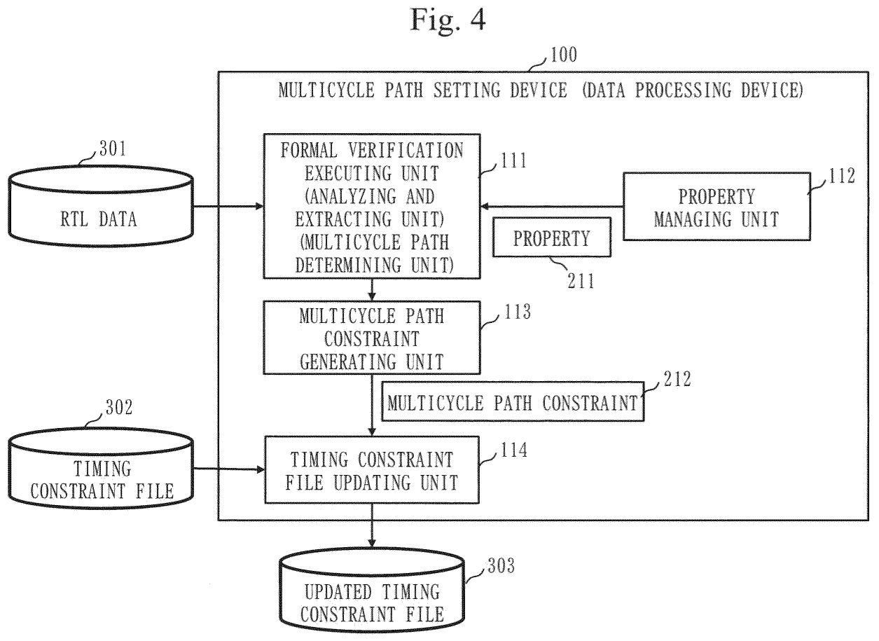

FIG. 4 depicts an example of functional structure of the multicycle path setting device 100.

First, the example of hardware structure of the multicycle path setting device 100 is described with reference to FIG. 3.

FIG. 3 depicts the example of hardware structure of the multicycle path setting device 100 according to the present embodiment.

The multicycle path setting device 100 according to the present embodiment is a computer. The multicycle path setting device 100 corresponds to a data processing device. The operation procedure of the multicycle path setting device 100 corresponds to a data processing method. Also, a program achieving the operation of the multicycle path setting device 100 corresponds to a data processing program.

The multicycle path setting device 100 includes a processor 901, a main storage device 902, an auxiliary storage device 903, and a communication device 904 as hardware. Although not depicted in the drawing, an input/output device such as a keyboard, mouse, or display may be included in the multicycle path setting device 100.

Also, the multicycle path setting device 100 includes a formal verification executing unit 111, a property managing unit 112, a multicycle path constraint generating unit 113, and a timing constraint file updating unit 114 as functional structures. The functions of the formal verification executing unit 111, the property managing unit 112, the multicycle path constraint generating unit 113, and the timing constraint file updating unit 114 are implemented by a program, for example.

In the auxiliary storage device 903, programs implementing the functions of the formal verification executing unit 111, the property managing unit 112, the multicycle path constraint generating unit 113, and the timing constraint file updating unit 114 are stored.

These programs are loaded from the auxiliary storage device 903 into the main storage device 902. Then, the processor 901 executes these programs to perform operations of the formal verification executing unit 111, the property managing unit 112, the multicycle path constraint generating unit 113, and the timing constraint file updating unit 114 described further below.

FIG. 3 schematically depicts a state in which the processor 901 is executing the programs implementing the functions of the formal verification executing unit 111, the property managing unit 112, the multicycle path constraint generating unit 113, and the timing constraint file updating unit 114.

Next, the example of functional structure of the multicycle path setting device 100 is described with reference to FIG. 4.

The formal verification executing unit 111 acquires RTL data 301.

In the RTL data 301, the circuit structure of a semiconductor integrated circuit as a design target is described. In the present embodiment, as described above, in the semiconductor integrated circuit, two or more FFs are connected as two or more storage elements. Also, the semiconductor integrated circuit operates based on the clock cycle.

The formal verification executing unit 111 may acquire a net list in place of the RTL data 301. When the formal verification executing unit 111 acquires a net list, the RTL data 301 in the following description is read as the net list.

The formal verification executing unit 111 further performs a static analysis of the RTL data 301 by using a property 211 (design specifications) supplied from the property managing unit 112.

In the present embodiment, the property 211 is a description in which “a period in which no signal transition occurs is always two or more clock cycles”.

The formal verification executing unit 111 performs a static analysis of the RTL data 301 and extracts a FF matching the property 211 as a transition pause FF. Specifically, the formal verification executing unit 111 extracts, from two or more FFs, a FF with a shortest transition pause time being two or more clock cycles as a transition pause FF. In other words, the formal verification executing unit 111 does not extract a FF in which a timing when signal transition is made in one cycle clock is present as a transition pause FF. The transition pause FF is an example of a transition pause storage element.

The formal verification executing unit 111 performs verification of specifications by a formal verification scheme using the property 211 as a static analysis.

The formal verification scheme is a scheme of mathematically analyzing the circuit structure of the RTL data 301 and the property 211 to statically verify the correctness of the semiconductor integrated circuit. In the formal verification scheme, a verification pattern required in Patent Literature 1 is not required. Also, according to the formal verification scheme, it is possible to exhaustively verify the correctness of the semiconductor integrated circuit. As tools for the formal verification scheme, “Jasper Gold” by Cadence, “VC Formal” by Synopsys Inc., and others have been provided.

Also, the formal verification executing unit 111 extracts a FF of a connection source of the transition pause FF as a connection-source FF from two or more FFs. Specifically, the formal verification executing unit 111 extracts a connection-source FF by tracing an input signal line of the transition pause FF in the RTL data 301. The connection-source FF is an example of a connection-source storage element.

Furthermore, the formal verification executing unit 111 determines to set a multicycle path between the transition pause FF and the connection-source FF.

The formal verification executing unit 111 corresponds to an analyzing and extracting unit and a multicycle path determining unit.

Also, the process to be performed by the formal verification executing unit 111 corresponds to an analyzing and extracting process and a multicycle path determining process.

The property managing unit 112 manages the property 211 for use in static analysis of the RTL data 301 by the formal verification executing unit 111.

The property 211 is generated by the designer of the semiconductor integrated circuit. The property managing unit 112 acquires the property 211 from the designer, and stores the acquired property 211 in the auxiliary storage device 903.

Then, when the formal verification executing unit 111 performs a static analysis of the RTL data 301, the property managing unit 112 reads the property 211 from the auxiliary storage device 903, and supplies the read property 211 to the formal verification executing unit 111.

The multicycle path constraint generating unit 113 generates a multicycle path constraint 212 of the multicycle path being a setting target determined by the formal verification executing unit 111.

In the multicycle path constraint 212, information about the multicycle path being the setting target is described.

The timing constraint file updating unit 114 acquires a timing constraint file 302.

Furthermore, the timing constraint file updating unit 114 adds the multicycle path constraint 212 generated by the multicycle path constraint generating unit 113 to the timing constraint file 302.

The timing constraint file updating unit 114 outputs the timing constraint file 302 added with the multicycle path constraint 212 as an updated timing constraint file 303.

### Description of Operation

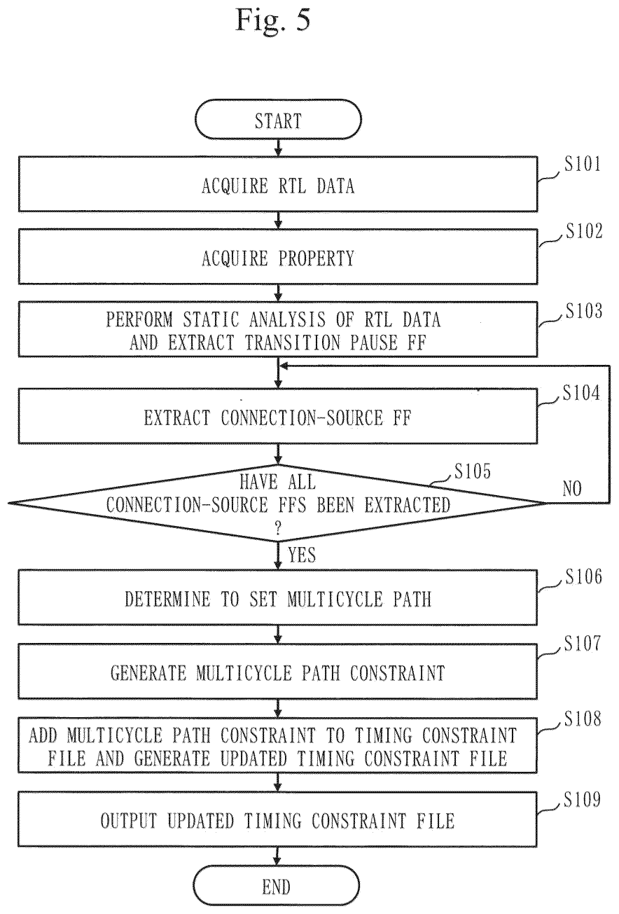

Next, an example of operation of the multicycle path setting device 100 according to the present embodiment is described with reference to FIG. 5.

First, at step S101, the formal verification executing unit 111 acquires the RTL data 301.

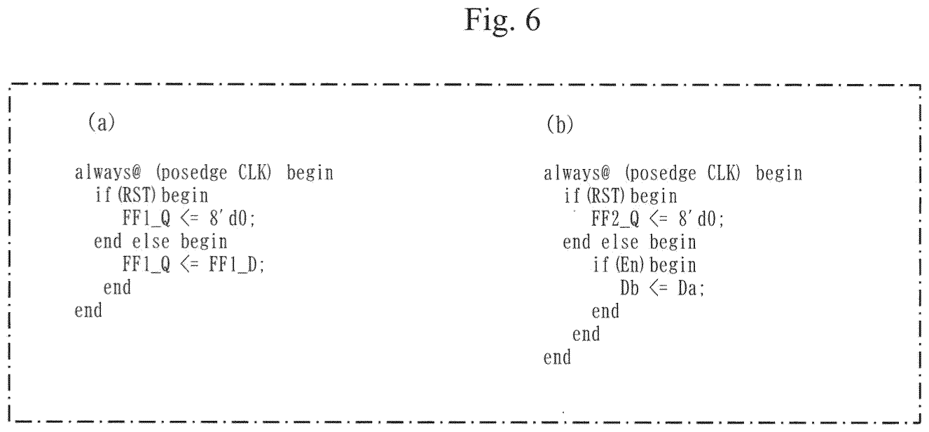

Here, it is assumed that a description depicted in FIG. 6 is included in the RTL data 301 as a RTL description of the circuit structure depicted in FIG. 1.
(a) of FIG. 6 depicts a RTL description of FF1_reg of FIG. 1, and (b) of FIG. 6 depicts a RTL description of FF2_reg of FIG. 1.

Next, at step S102, the formal verification executing unit 111 acquires the property 211 from the property managing unit 112.

As described above, the property 211 is a description in which “a period in which no signal transition occurs is always two or more clock cycles”.

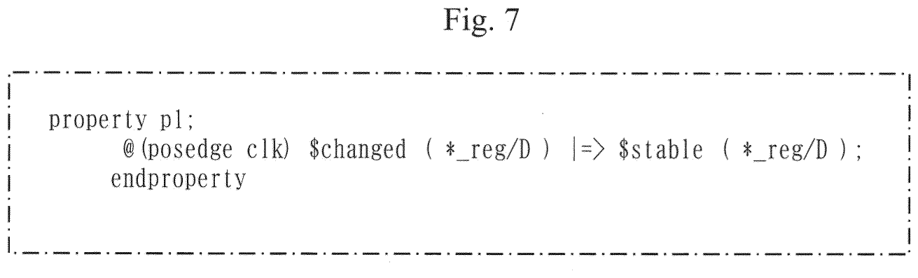

In the present embodiment, it is assumed that the formal verification executing unit 111 uses the property 211 depicted in FIG. 7.

Next, at step S103, the formal verification executing unit 111 performs a static analysis of the RTL data 301 by using the property 211, and extracts a transition pause FF.

When there are a plurality of FFs matching the description of the property 211, the formal verification executing unit 111 extracts the plurality of FFs as transition pause FFs.

In the example of FIG. 1, since FF2_reg corresponds to a transition pause FF, the formal verification executing unit 111 extracts FF2_reg as a transition pause FF.

Next, at step S104, the formal verification executing unit 111 traces the input signal line of the transition pause FF in the RTL data 301 to extract a connection-source FF.

When a plurality of connection-source FFs are present for one transition pause FF, the formal verification executing unit 111 extracts the plurality of connection-source FFs.

If a plurality of transition pause FFs have been extracted at step S103, the formal verification executing unit 111 performs step S104 for each transition pause FF.

In the example of FIG. 1, the formal verification executing unit 111 extracts FF1_reg as a connection-source FF of FF2_reg.

Next, at step S105, the formal verification executing unit 111 determines whether all connection-source FFs have been extracted for all transition pause FFs.

If a non-extracted connection-source FF is present, the formal verification executing unit 111 repeats step S104.

If all connection-source FFs have been extracted for all transition pause FFs, the process proceeds to step S106.

Next, at step S106, the formal verification executing unit 111 determines, for each transition pause FF, to set a multicycle path between the transition pause FF and the corresponding connection-source FF. More specifically, the formal verification executing unit 111 determines to set a multicycle path corresponding to two clock cycles between the transition pause FF and the connection-source FF.

Then, the formal verification executing unit 111 generates multicycle path information indicating a set of the transition pause FF and the connection-source FF being a setting target of a multicycle path, and outputs the multicycle path information to the multicycle path constraint generating unit 113.

In the example of FIG. 1, the formal verification executing unit 111 determines to set a multicycle path between FF1_reg and FF2_reg, and generates multicycle path information indicating FF1_reg and FF2_reg.

Next, at step S107, the multicycle path constraint generating unit 113 generates the multicycle path constraint 212 based on the multicycle path information.

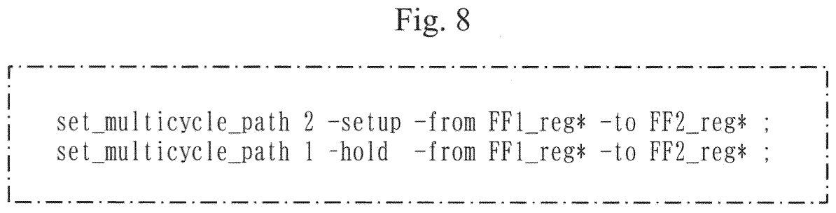

In the example of FIG. 1, the multicycle path constraint generating unit 113 generates the multicycle path constraint 212 depicted in FIG. 8 for the multicycle path between FF1_reg and FF2_reg.

Then, the multicycle path constraint generating unit 113 outputs the generated multicycle path constraint 212 to the timing constraint file updating unit 114.

Next, at step S108, the timing constraint file updating unit 114 adds the multicycle path constraint 212 to the timing constraint file 302 to generate the updated timing constraint file 303.

Lastly, at step S109, the timing constraint file updating unit 114 outputs the generated updated timing constraint file 303.

### Description of Effects of Embodiment

As described above, according to the present embodiment, a multicycle path can be accurately set without using a verification pattern and putting a load on the designer of the semiconductor integrated circuit.

More specifically, in the present embodiment, an analysis of the RTL data by a formal verification scheme of mathematically analyzing the circuit structure is performed, thereby allowing a multicycle path to be exhaustively extracted without using a verification pattern. Also, since an updated timing constraint file reflecting the extracted multicycle path is automatically generated, a multicycle path can be accurately set without putting a load on the designer.

If the setting of the multicycle path has a mistake (for example, if a multicycle path is erroneously set to a path in which a signal transition has to occur by one clock cycle), a critical trouble occurs, such as that the semiconductor integrated circuit does not operate.

In a conventional method, a mistake in setting of a multicycle path can easily occur due to a delusion of the designer or verification pattern insufficiency. On the other hand, in the method using the formal verification scheme according to the present embodiment, no mistake can occur.

Furthermore, since the formal verification scheme of mathematically analyzing the circuit structure is used, a (designer-unintended) multicycle path that cannot be extracted by the conventional method can be extracted.

### Embodiment 2

In the present embodiment, differences from Embodiment 1 are mainly described.

Note that matters not described below are similar to those in Embodiment 1.

In Embodiment 1, the property 211 “a period in which no signal transition occurs is always two or more clock cycles” is used. Also, in Embodiment 1, a multicycle path of two clock cycles is set between the transition pause FF and the connection-source FF.

In the present embodiment, a property supporting also a clock cycle with a value larger than two clock cycles (for example, three clock cycles, four clock cycles) is used. With this, in the present embodiment, a multicycle path of a clock cycle with a value large than two clock cycles is set.

### Description of Structure

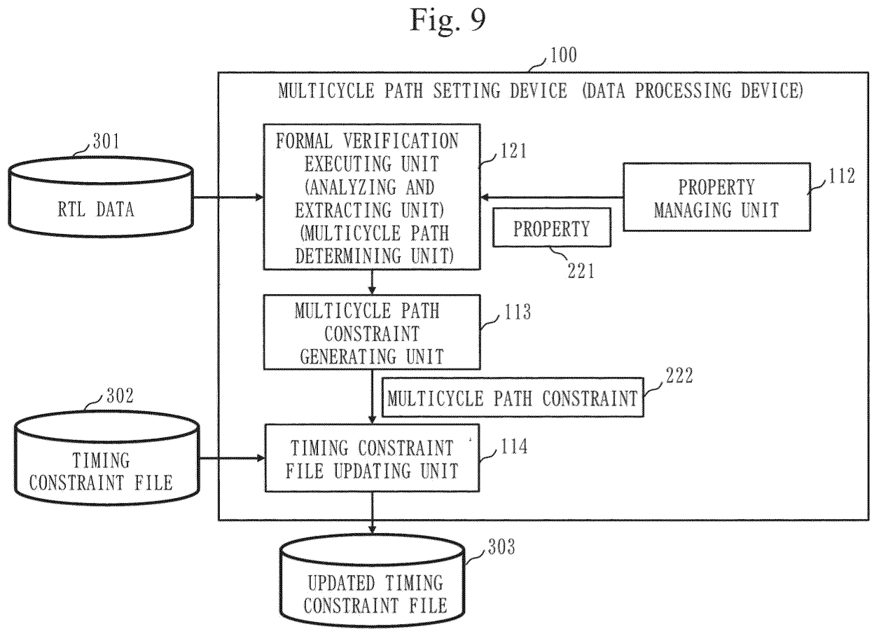

FIG. 9 depicts an example of functional structure of the multicycle path setting device 100 according to the present embodiment. Note that an example of hardware structure of the multicycle path setting device 100 according to the present embodiment is as depicted in FIG. 3.

In FIG. 9, compared with FIG. 4, in place of the formal verification executing unit 111, a formal verification executing unit 121 is included. Also, in place of the property 211, a property 221 is included. Furthermore, in place of the multicycle path constraint 212, a multicycle path constraint 222 is included.

Components other than the formal verification executing unit 121, the property 221, and the multicycle path constraint 222 are identical to those depicted in FIG. 1. Therefore, only the formal verification executing unit 121, the property 221, and the multicycle path constraint 222 are described herein.

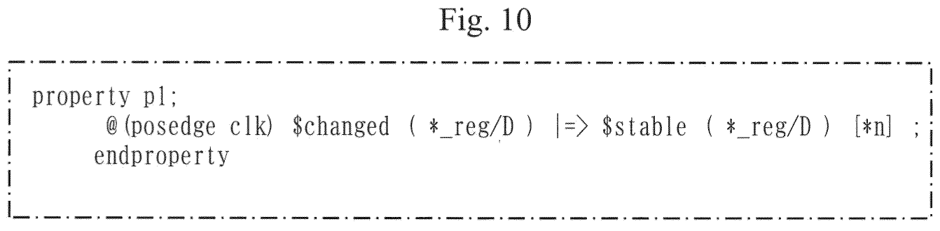

In the present embodiment, the property 221 is described as in FIG. 10.

In the property 221 of FIG. 10, compared with the property 211 of FIG. 7, [*n] is added after “$stable(*_reg/D)”.

“n” is a variable value.

A property set with [*1](“n=1”) is used to extract FF with a transition pause time being equal to or more than two clock cycles.

Similarly, a property set with [*2](“n=2”) is used to extract FF with a transition pause time being equal to or more than three clock cycles.

In this manner, a property set with [*(j−1)](“n=(j−1)”) is used to extract FF with a transition pause time equal to or more than j clock cycles. That is, in a static analysis using the property set with [*(j−1)](“n=(j−1)”), FF with a transition pause time equal to or more than j clock cycles is extracted.

In the present embodiment, the formal verification executing unit 121 sets “1” and one or more “values larger than 1” to “n” of the property 221. With this, the formal verification executing unit 121 specifies each of two clock cycles and one or more clock cycles with a value larger than two clock cycles (for example, three clock cycles, four clock cycles) as a specified clock cycle. For example, the formal verification executing unit 121 increments the value of “n” of the property 221 by 1, 2, 3, 4 . . . , and can specify each of two clock cycles and a plurality of clock cycles with a value larger than two clock cycles as a specified clock cycle.

In place of this, the formal verification executing unit 121 may decrease the value of “n” of the property 221 from “m”, which is a predefined upper limit value, to “1”, which is a lower limit value. With this, the formal verification executing unit 121 may specify each of two clock cycles and one or more clock cycles with a value larger than two clock cycles (for example, three clock cycles, four clock cycles) as a specified clock cycle. For example, the formal verification executing unit 121 may decrement the value of “n” of the property 221 to m, (m−1), (m−2) . . . to decrement the value to 1 and specify each of a plurality of clock cycles with a value larger than two clock cycles and two clock cycles as a specified clock cycle. Note that any upper limit value m can be determined by the designer.

In the following, unless otherwise noted, it is assumed that the formal verification executing unit 121 changes the value of “n” by incrementing.

Also, the formal verification executing unit 121 extracts, for each specified clock cycle, a FF with a shortest transition pause time matching the specified clock cycle as a transition pause FF. Then, the formal verification executing unit 121 extracts a FF of a connection source of the transition pause FF as a connection-source FF.

That is, the formal verification executing unit 121 extracts a transition pause FF and a connection-source FF for each value of n.

Then, the formal verification executing unit 121 determines, for each specified clock cycle, to set a multicycle path corresponding to the specified clock cycle between the transition pause FF and the connection-source FF extracted for the specified clock cycle.

That is, the formal verification executing unit 121 determines, for each value of n, to set a multicycle path corresponding to the value of n between the transition pause FF and the connection-source FF.

In this manner, the formal verification executing unit 121 determines to set a multicycle path corresponding to the value of n for each value of n. Thus, in the present embodiment, in the multicycle path constraint 222 generated by the multicycle path constraint generating unit 113, for each value of n, a constraint of the multicycle path corresponding to the value of n is described.

The formal verification executing unit 121 according to the present embodiment also corresponds to an analyzing and extracting unit and a multicycle path determining unit.

As with the formal verification executing unit 111 and so forth, the function of the formal verification executing unit 121 is also implemented by programs. The programs implementing the function of the formal verification executing unit 121 is executed by the processor 901.

### Description of Operation

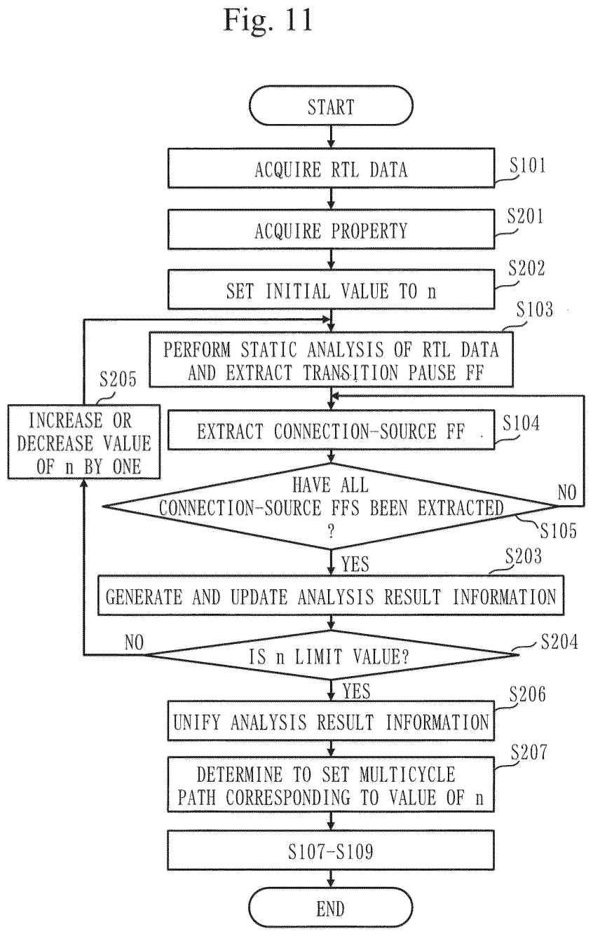

Next, an example of operation of the multicycle path setting device 100 according to the present embodiment is described with reference to FIG. 11.

Note that in FIG. 11, a process at step S10X is identical to the process depicted in FIG. 4. A process at step S20X is a new process not included in the flow of FIG. 4.

First, at step S101, the formal verification executing unit 121 acquires the RTL data 301.

Next, at step S201, the formal verification executing unit 121 acquires the property 221 from the property managing unit 112.

As described by using FIG. 10, [*n] is included in the property 221.

Next, at step S202, the formal verification executing unit 121 sets an initial value to “n” of the property 221.

When the value of “n” is changed by incrementing, the formal verification executing unit 121 sets “n=1” as an initial value. On the other hand, when the value of “n” is changed by decrementing, the formal verification executing unit 121 sets “n=m” as an initial value.

Next, at step S103, the formal verification executing unit 121 performs a static analysis of the RTL data 301 by using the property 221, and extracts a transition pause FF.

When there are a plurality of FFs matching the description of the property 221, the formal verification executing unit 121 extracts the plurality of FFs as transition pause FFs.

Next, at step S104, the formal verification executing unit 121 traces the input signal line of the transition pause FF in the RTL data 301 to extract a connection-source FF.

When a plurality of connection-source FFs are present in one transition pause FF, the formal verification executing unit 121 extracts the plurality of connection-source FFs.

If a plurality of transition pause FFs have been extracted at step S103, the formal verification executing unit 121 performs step S104 for each transition pause FF.

Next, at step S105, the formal verification executing unit 121 determines whether all connection-source FFs have been extracted for all transition pause FFs.

If a non-extracted connection-source FF is present, the formal verification executing unit 121 repeats step S104.

If all connection-source FFs have been extracted for all transition pause FFs, the process proceeds to step S203.

At step S203, the formal verification executing unit 121 generates and updates analysis result information.

The analysis result information is information described with the value of n, the transition pause FF, and the connection-source FF in association with one another.

As described above, in a static analysis using the property of “n=j−1)”, a FF with a transition pause time being j clock cycle or more is extracted.

For example, in a static analysis using the property of “n=1”, a FF with a transition pause time equal to or more than two clock cycles is extracted. The FF with a transition pause time equal to or more than two clock cycles includes a FF with a transition pause time being two clock cycles and a FF with a transition pause time being larger than two clock cycles.

It is assumed that the formal verification executing unit 121 performs a static analysis using the property of “n=1” at step S103. In this case, at step S203 immediately thereafter, the formal verification executing unit 121 generates analysis result information in which “n=1”, all FFs (transition pause FFs) with a transition pause time equal to or more than two clock cycles, and connection-source FFs of these are described in association with one another.

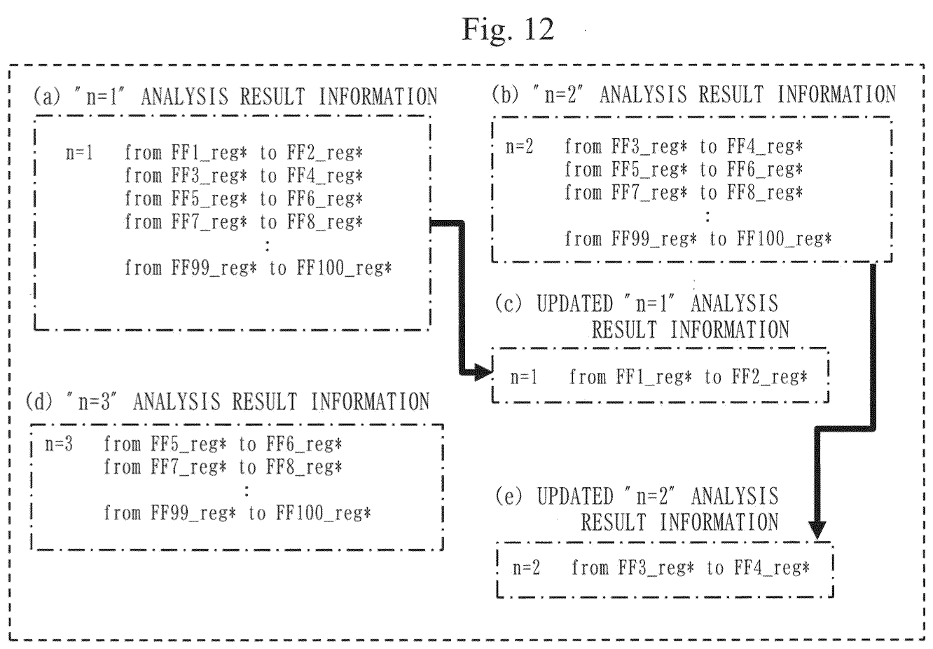

At step S203 after the static analysis using the property of “n=1”, it is assumed that the formal verification executing unit 121 generates “n=1” analysis result information of (a) of FIG. 12.

The formal verification executing unit 121 performs a static analysis using the property of “n=2” at the next step S103. Then, at step S203 immediately thereafter, the formal verification executing unit 121 generates analysis result information in which “n=2”, all FFs (transition pause FFs) with a transition pause time equal to or more than three clock cycles, and connection-source FFs of these are described in association with one another.

At step S203 after the static analysis using the property of “n=2”, it is assumed that the formal verification executing unit 121 generates “n=2” analysis result information of (b) of FIG. 12.

The formal verification executing unit 121 compares the “n=1” analysis result information with the “n=2” analysis result information. Then, the formal verification executing unit 121 deletes a row overlapping the “n=2” analysis result information from the “n=1” analysis result information. As a result, the formal verification executing unit 121 updates the “n=1” analysis result information to updated “n=1” analysis result information in (c) of FIG. 12.

Next, at step S203 after the static analysis using the property of “n=3”, it is assumed that the formal verification executing unit 121 generates “n=3” analysis result information of (d) of FIG. 12.

The formal verification executing unit 121 compares the “n=2” analysis result information with the “n=3” analysis result information. Then, the formal verification executing unit 121 deletes a row overlapping the “n=3” analysis result information from the “n=2” analysis result information. As a result, the formal verification executing unit 121 updates the “n=2” analysis result information to updated “n=2” analysis result information in (e) of FIG. 12.

In this manner, the formal verification executing unit 121 increments the value of n and generates analysis result information for the value of n after incrementing and, by using the analysis result information for the value of n after incrementing, updates the analysis result information generated for the value of n before incrementing.

The formal verification executing unit 121 stores the analysis result information and the updated analysis result information in at least any of the main storage device 902, the auxiliary storage device 903, and a cache memory not depicted in FIG. 3.

Returning to FIG. 11, at step S204, the formal verification executing unit 121 determines whether the value of n has reached a limit value.

When the formal verification executing unit 121 is incrementing the value of n, the limit value is the upper limit value “m”. On the other hand, when the formal verification executing unit 121 is decrementing the value of n, the limit value is the lower limit value “1”.

If the value of n has not reached the limit value, the process proceeds to step S205. On the other hand, if the value of n has reached the limit value, the process proceeds to step S206.

At step S205, the formal verification executing unit 121 increases the value of n by one or decreases it by one. That is, the formal verification executing unit 121 increases the value of n by one when incrementing the value of n. On the other hand, the formal verification executing unit 121 decreases the value of n by one when decrementing the value of n.

Then, the formal verification executing unit 121 performs processes at step S103 onward with a new value of n.

At step S206, the formal verification executing unit 121 unifies a plurality of pieces of analysis result information.

Analysis result information acquired by unification at step S206 is referred to as unified analysis result information.

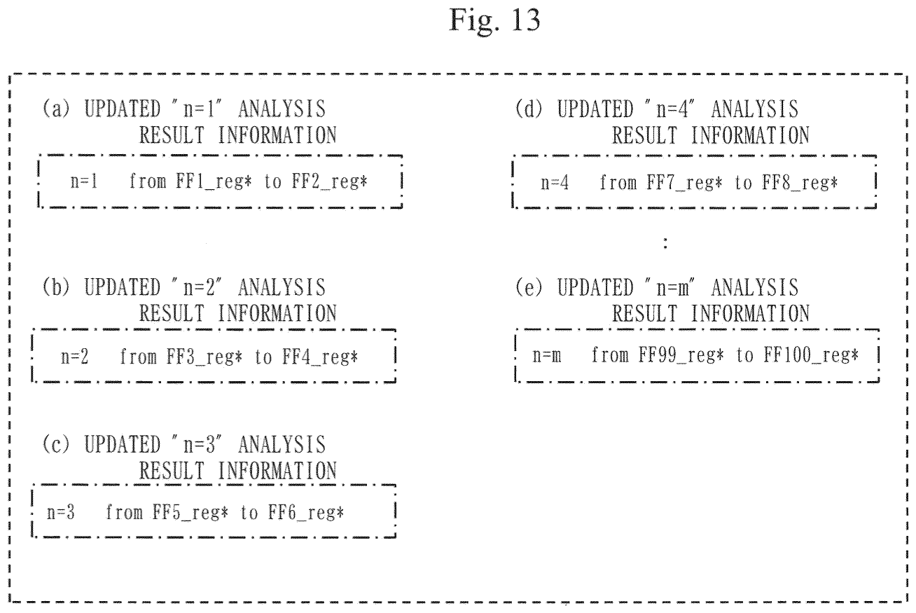

It is assumed that, with generation and updating of the analysis result information described with reference to FIG. 12, for example, updated “n=m” analysis result information ((e) of FIG. 13) has been acquired from updated “n=1” analysis result information ((a) of FIG. 13) depicted in FIG. 13.

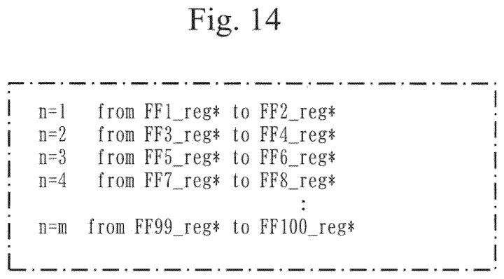

Here, the formal verification executing unit 121 unifies the updated “n=1” analysis result information to the updated “n=m” analysis result information to acquire unified analysis result information depicted in FIG. 14.

In the unified analysis result information of FIG. 14, the updated “n=1” analysis result information to the updated “n=m” analysis result information are unified.

Next, at step S207, the formal verification executing unit 121 determines, for each value of n of the unified analysis result information, to set a multicycle path of a number of clock cycles corresponding to the value of n between the transition pause FF and the connection-source FF.

In the example of the unified analysis result information of FIG. 14, the formal verification executing unit 121 determines, for “n=1”, to set a multicycle path of two clock cycles between FF1_reg and FF2_reg.

Also, the formal verification executing unit 121 determines, for “n=2”, to set a multicycle path of three clock cycles between FF3_reg and FF4_reg.

Also, the formal verification executing unit 121 determines, for “n=3”, to set a multicycle path of four clock cycles between FF5_reg and FF6_reg.

Also for another value of n, the formal verification executing unit 121 determines to set a multicycle path corresponding to the value of n between the transition pause FF and the connection-source FF in a similar procedure.

Then, the formal verification executing unit 121 generates, for each value of n, multicycle path information indicating a set of the transition pause FF and the connection-source FF, and outputs the multicycle path information to the multicycle path constraint generating unit 113.

Thereafter, as with Embodiment 1, step S107 to step S109 are performed.

At step S107, the multicycle path constraint generating unit 113 generates the multicycle path constraint 222 based on the multicycle path information.

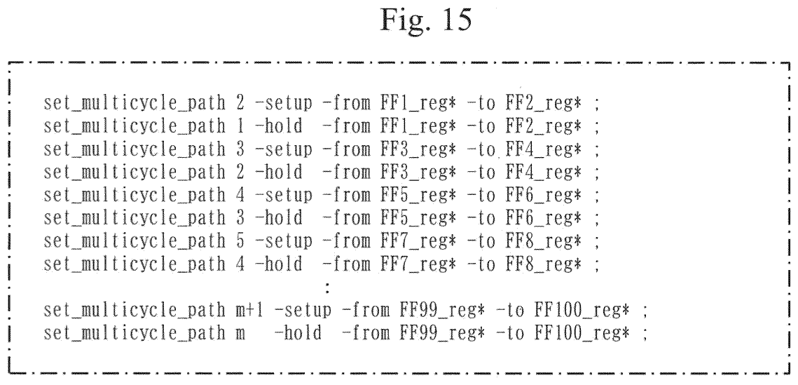

In the present embodiment, the multicycle path constraint generating unit 113 generates the multicycle path constraint 222 depicted in FIG. 15. In the multicycle path constraint 222 depicted in FIG. 15, a constraint of the multicycle path for (n+1) clock cycles are described for each value of n.

The multicycle path constraint generating unit 113 outputs the generated multicycle path constraint 222 to the timing constraint file updating unit 114.

Next, at step S108, the timing constraint file updating unit 114 adds the multicycle path constraint 222 to the timing constraint file 302 to generate the updated timing constraint file 303.

Lastly, at step S109, the timing constraint file updating unit 114 outputs the generated updated timing constraint file 303.

### Description of Effects of Embodiment

In the present embodiment, a plurality of multicycle paths with different numbers of clock cycles can be set in the semiconductor integrated circuit.

Thus, compared with Embodiment 1, it is possible to further facilitate the layout of the semiconductor integrated circuit and reduce power consumption.

Note that in the above description, when the value of n is changed by incrementing, the formal verification executing unit 121 increases the value of n until the value of n reaches the upper limit value m. In place of this, even if the value of n does not reach the upper limit value m, when no transition pause FF can be extracted at step S103, the formal verification executing unit 121 may cause the process to end the loop of step S103 to step S205 and make a transition to step S206. For example, when m=10, if no transition pause FF can be extracted at step S103 when n=4, the loop of step S103 to step S205 may be ended, and the process is caused to make a transition to step S206. Note that in this case, it can be found that the maximum number of clock cycles included in the semiconductor integrated circuit is 4 (n=3).

### Embodiment 3

In the present embodiment, a structure enabling clock gating in a multicycle path period (period in which no signal transition occurs) is described.

Clock gating is a scheme of reducing power consumption of a semiconductor integrated circuit by stopping clock supply.

In the present embodiment, differences from Embodiment 2 are mainly described.

Note that matters not described below are similar to those in Embodiment 2.

### Description of Structure

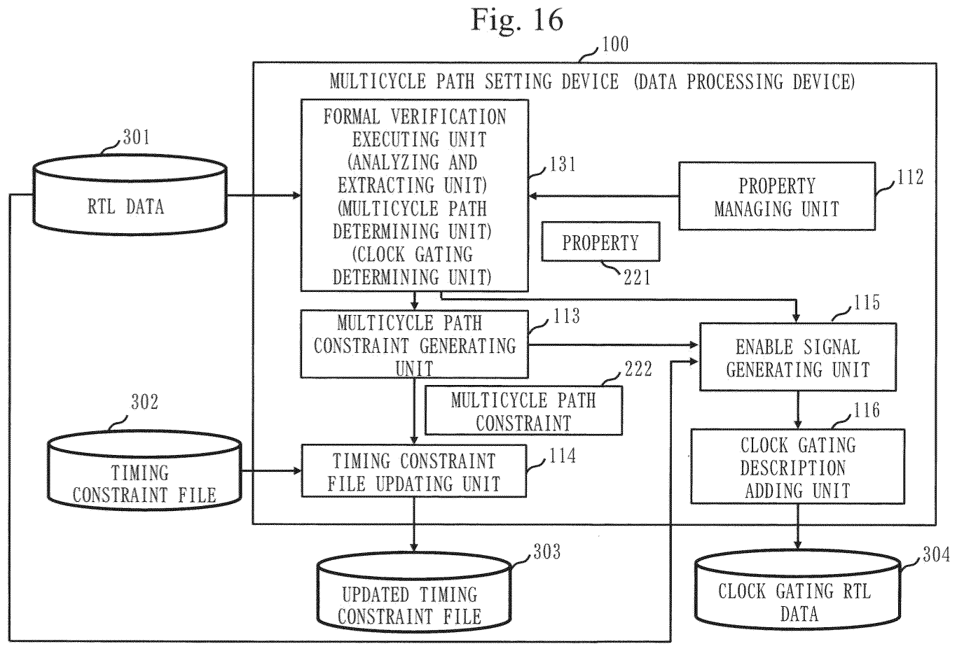

FIG. 16 depicts an example of functional structure of the multicycle path setting device 100 according to the present embodiment. Note that an example of hardware structure of the multicycle path setting device 100 according to the present embodiment is as depicted in FIG. 3.

In FIG. 16, compared with FIG. 9, in place of the formal verification executing unit 121, a formal verification executing unit 131 is included. Also, an enable signal generating unit 115, a clock gating description adding unit 116, and clock gating RTL data 304 are added.

Components other than the formal verification executing unit 131, the enable signal generating unit 115, the clock gating description adding unit 116, and the clock gating RTL data 304 are identical to those depicted in FIG. 9. Therefore, only the formal verification executing unit 131, the enable signal generating unit 115, the clock gating description adding unit 116, and the clock gating RTL data 304 are described herein.

As with the formal verification executing unit 121, the formal verification executing unit 131 changes the value of n of the property 221 and extracts a transition pause FF and a connection-source FF for each value of n. Also, the formal verification executing unit 131 determines, for each value of n, to set a multicycle path for (n+1) clock cycles between the transition pause FF and the connection-source FF.

Furthermore, the formal verification executing unit 131 determines, for each multicycle path, to add a clock gating circuit performing clock gating in a multicycle path period to the semiconductor integrated circuit.

As with the formal verification executing unit 121, the formal verification executing unit 131 also corresponds to the analyzing and extracting unit and the multicycle path determining unit. Also, the formal verification executing unit 131 also corresponds to a clock gating determining unit.

The enable signal generating unit 115 acquires the RTL data 301.

Also, the enable signal generating unit 115 acquires the multicycle path constraint 222.

Then, the enable signal generating unit 115 generates an enable signal by using the multicycle path constraint 222, and adds the enable signal to the RTL data 301. The enable signal is a signal enabling clock gating in a multicycle path period.

The enable signal generating unit 115 outputs the RTL data 301 added with the enable signal to the clock gating description adding unit 116.

The clock gating description adding unit 116 generates a RTL description for adding a clock gating circuit to the semiconductor integrated circuit (hereinafter referred to as clock gating description). Then, the clock gating description adding unit 116 adds the clock gating description to the RTL data 301.

Also, the clock gating description adding unit 116 outputs the RTL data 301 added with the clock gating description as the clock gating RTL data 304.

In the clock gating RTL data 304, the circuit structure of the semiconductor integrated circuit added with the clock gating circuit is described.

As with the formal verification executing unit 111 and so forth, the functions of the formal verification executing unit 131, the enable signal generating unit 115, and the clock gating description adding unit 116 are also implemented by programs. The programs implementing the functions of the formal verification executing unit 131, the enable signal generating unit 115, and the clock gating description adding unit 116 are executed by the processor 901.

### Description of Operation

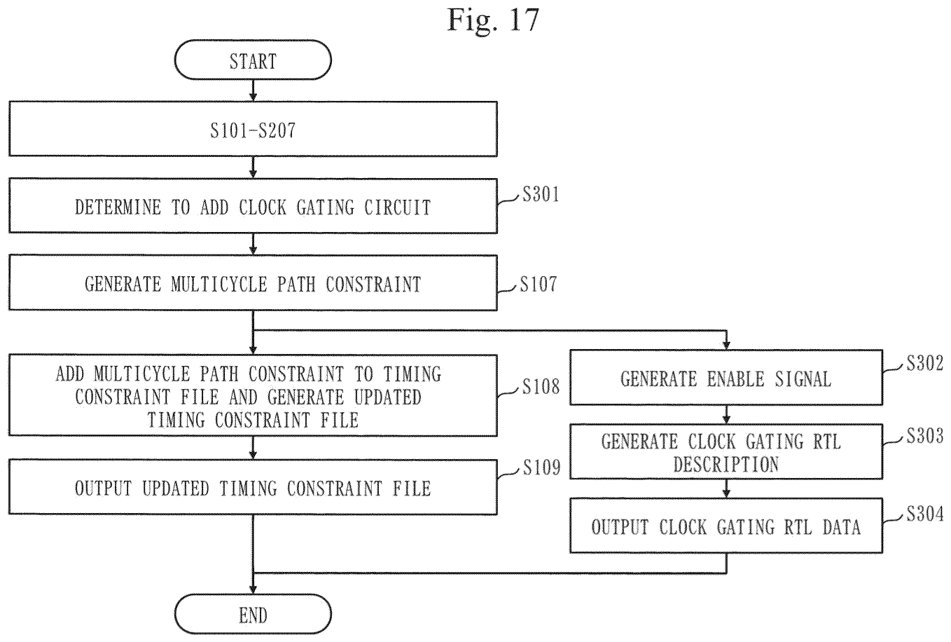

Next, an example of operation of the multicycle path setting device 100 according to the present embodiment is described with reference to FIG. 17. Note that in FIG. 17, processes at step S10X and step S20X are identical to the processes depicted in FIG. 11. A process at step S30X is a new process not included in the flow of FIG. 11.

The flow of FIG. 17 is performed after the process is completed up to step S207 depicted in FIG. 11.

First, at step S301, the formal verification executing unit 131 determines to add a clock gating circuit to the semiconductor integrated circuit.

More specifically, the formal verification executing unit 131 determines, for each multicycle path determined at step S207, to add a clock gating circuit that performs clock gating in a multicycle path period.

Next, at step S107, as with Embodiment 1, the multicycle path constraint generating unit 113 generates the multicycle path constraint 222.

In the present embodiment, the multicycle path constraint generating unit 113 outputs the generated multicycle path constraint 222 to the timing constraint file updating unit 114 and the enable signal generating unit 115.

At step S108, as with Embodiment 1, the timing constraint file updating unit 114 adds the multicycle path constraint 222 to the timing constraint file 302 to generate the updated timing constraint file 303.

Also, at step S109, as with Embodiment 1, the timing constraint file updating unit 114 outputs the generated updated timing constraint file 303.

At step S302, the enable signal generating unit 115 refers to the multicycle path constraint 222 acquired from the multicycle path constraint generating unit 113, and generates an enable signal. The enable signal generated by the enable signal generating unit 115 is a signal for enabling clock gating in a multicycle path period.

If the enable signal concerned has been already present in the RTL data 301, the enable signal generating unit 115 does not generate an enable signal. On the other hand, if the enable signal concerned is not included in the RTL data 301, the enable signal generating unit 115 calculates an output timing of an enable signal, and adds the enable signal to the RTL data 301.

The enable signal generating unit 115 outputs the RTL data 301 added with the enable signal to the clock gating description adding unit 116.

At step S303, the clock gating description adding unit 116 generates a clock gating description based on the RTL data 301 acquired from the enable signal generating unit 115.

The clock gating description adding unit 116 generates a clock gating description by using, for example, the scheme described in JP 5143061 as a reference literature.

Then, at step S304, the clock gating description adding unit 116 adds the clock gating description to the RTL data 301. Also, the clock gating description adding unit 116 outputs the RTL data 301 added with the clock gating description as the clock gating RTL data 304.

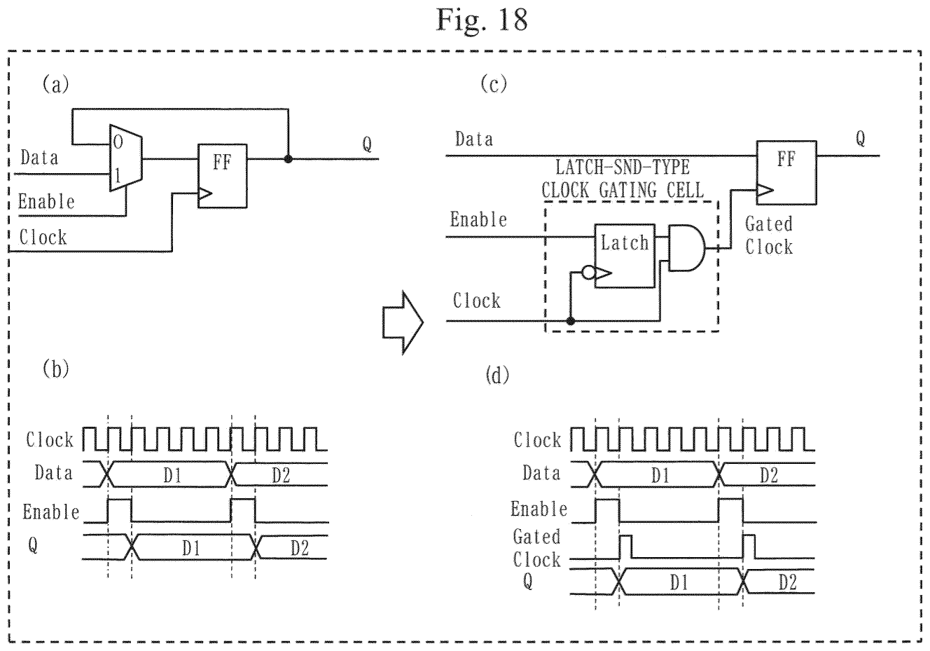

FIG. 18 describes an example of operation of the enable signal generating unit 115 and the clock gating description adding unit 116.
(a) of FIG. 18 depicts an example of the RTL data 301.
(b) of FIG. 18 is a timing waveform diagram of the circuit structure of (a) of FIG. 18.

The enable signal turns ON only at the start timing of data input.

In the example of (a) and (b) of FIG. 18, since an enable signal has been already included in the RTL data 301, the enable signal generating unit 115 does not generate an enable signal. If no enable signal is included in the RTL data 301, an enable signal depicted in (a) and (b) of FIG. 18 is generated, and the enable signal is added to the RTL data 301.
(c) of FIG. 18 depicts the clock gating RTL data 304 generated by the clock gating description adding unit 116. In the clock gating RTL data 304, by the clock gating description adding unit 116, a LATCH-AND-type clock gating cell and its signal line are added as clock gating descriptions.
(d) of FIG. 18 is a timing waveform diagram of the circuit structure of (c) of FIG. 18.

In (d) of FIG. 18, immediately after the enable signal turns ON, a Gated Clock signal from the LATCH-AND-type clock gating cell to the FF turns ON. Thereafter, the Gated Clock signal turns OFF. Based on the enable signal, the clock gating description adding unit 116 generates a clock gating description corresponding to the clock gating circuit and the Gated Clock signal depicted in (c) and (d) of FIG. 18. With this, clock gating is achieved.

### Description of Effects of Embodiment

In the present embodiment, clock gating can be performed between FFs set with the multicycle path and in a period without signal transition.

Thus, compared with Embodiment 2, more reduction in power consumption can be achieved.

### Embodiment 4

In the present embodiment, a structure enabling power gating in a multicycle path (period in which no signal transition occurs) is described.

Power gating is a scheme of partially stopping power supply to reduce power consumption of the semiconductor integrated circuit. In power gating, not only clock but also power supply to a related circuit is stopped. Thus, power consumption of the related circuit including leak power (power consumed even without operation) can be made basically zero.

In the present embodiment, differences from Embodiment 3 are mainly described.

Note that matters not described below are similar to those in Embodiment 3.

### Description of Structure

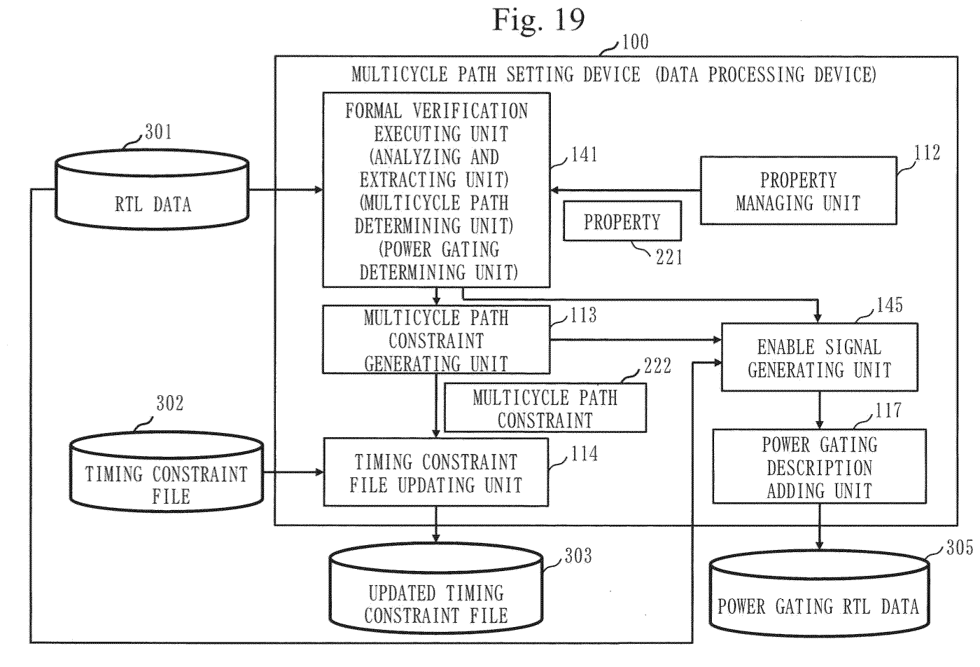

FIG. 19 depicts an example of functional structure of the multicycle path setting device 100 according to the present embodiment. Note that an example of hardware structure of the multicycle path setting device 100 according to the present embodiment is as depicted in FIG. 3.

In FIG. 19, compared with FIG. 16, in place of the formal verification executing unit 131, a formal verification executing unit 141 is included. Also, in place of the enable signal generating unit 115, an enable signal generating unit 145 is included. Furthermore, in place of the clock gating description adding unit 116, a power gating description adding unit 117 is included. Furthermore, in place of the clock gating RTL data 304, power gating RTL data 305 is included.

Components other than the formal verification executing unit 141, the enable signal generating unit 145, the power gating description adding unit 117, and the power gating RTL data 305 are identical to those depicted in FIG. 16. Therefore, only the formal verification executing unit 141, the enable signal generating unit 145, the power gating description adding unit 117, and the power gating RTL data 305 are described herein.

The formal verification executing unit 141 specifies a clock cycle longer than a power return time as a specified clock cycle. That is, the formal verification executing unit 141 changes the value of n of the property 221 in a range of times larger than the power return time and extracts a transition pause FF and a connection-source FF for each value of n. The power return time is a time required to restart power supply after power supply is stopped by power gating.

Also, the formal verification executing unit 141 determines, for each value of n, to set a multicycle path for (n+1) clock cycles between the transition pause FF and the connection-source FF.

Furthermore, the formal verification executing unit 141 determines, for each multicycle path, to add a power gating circuit performing power gating in a multicycle path period to the semiconductor integrated circuit.

As with the formal verification executing unit 121, the formal verification executing unit 141 also corresponds to the analyzing and extracting unit and the multicycle path determining unit. Also, the formal verification executing unit 141 also corresponds to a power gating determining unit.

The enable signal generating unit 145 acquires the RTL data 301.

Also, the enable signal generating unit 145 acquires the multicycle path constraint 222.

Then, the enable signal generating unit 145 generates an enable signal by using the multicycle path constraint 222, and adds the enable signal to the RTL data 301. The enable signal is a signal enabling power gating in a multicycle path period.

The enable signal generating unit 145 outputs the RTL data 301 added with the enable signal to the power gating description adding unit 117.

The operation of the enable signal generating unit 145 is substantially identical to the operation of the enable signal generating unit 115.

The power gating description adding unit 117 generates a RTL description for adding a power gating circuit to the semiconductor integrated circuit (hereinafter referred to as power gating description). Then, the power gating description adding unit 117 adds the power gating description to the RTL data 301.

Also, the power gating description adding unit 117 outputs the RTL data 301 added with the power gating description as the power gating RTL data 305.

In the power gating RTL data 305, the circuit structure of the semiconductor integrated circuit added with the power gating circuit is described.

As with the formal verification executing unit 111 and so forth, the functions of the formal verification executing unit 141, the enable signal generating unit 145, and the power gating description adding unit 117 are also implemented by programs. The programs implementing the functions of the formal verification executing unit 141, the enable signal generating unit 145, and the power gating description adding unit 117 are executed by the processor 901.

### Description of Operation

Next, an example of operation of the multicycle path setting device 100 according to the present embodiment is described.

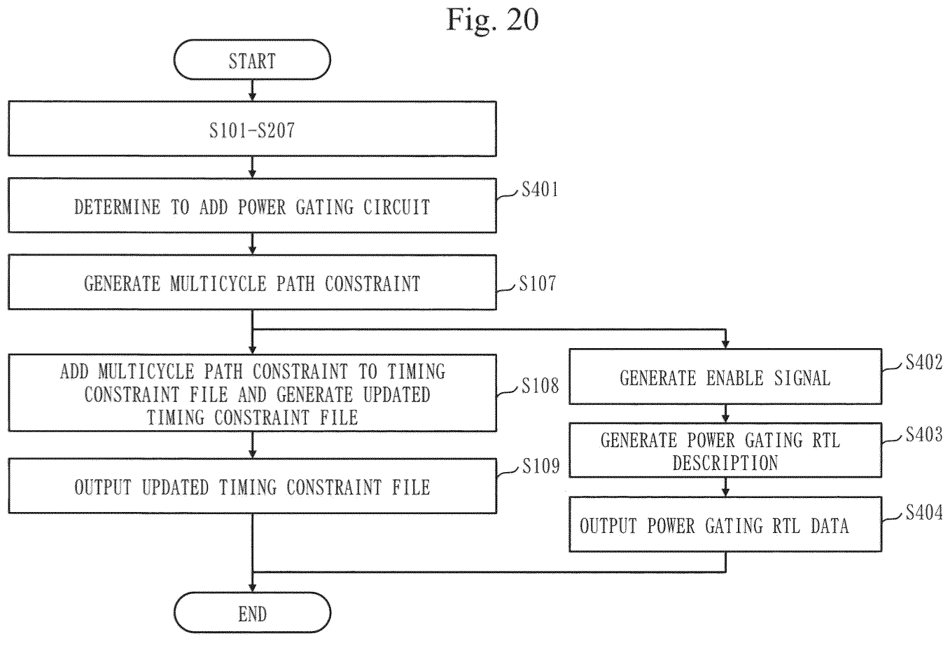

The example of operation of the multicycle path setting device 100 according to the present embodiment is described with reference to FIG. 11 and FIG. 20.

Step S101 and step S201 of FIG. 11 are as described in Embodiment 2 and description of them is omitted.

At step S202, the formal verification executing unit 141 sets an initial value to “n” of the property 221.

When the value of n is changed by incrementing, the formal verification executing unit 141 sets an initial value in accordance with a clock cycle slightly longer than the power return time. For example, when the power return time is 50 clock cycles, the formal verification executing unit 141 sets “50” in accordance with 51 clock cycles as an initial value of n. On the other hand, when the value of n is changed by decrementing, the formal verification executing unit 141 sets the initial value in accordance with a clock cycle significantly longer than the power return time.

Step S103 to step S207 are as described in Embodiment 2 and description of them is omitted.

The flow of FIG. 20 is performed after the process is completed up to step S207 depicted in FIG. 11.

First, at step S401, the formal verification executing unit 141 determines to add a power gating circuit to the semiconductor integrated circuit.

More specifically, the formal verification executing unit 141 determines, for each multicycle path determined at step S207, to add a power gating circuit that performs power gating in a multicycle path period.

Next, at step S107, as with Embodiment 1, the multicycle path constraint generating unit 113 generates the multicycle path constraint 222.

In the present embodiment, the multicycle path constraint generating unit 113 outputs the generated multicycle path constraint 222 to the timing constraint file updating unit 114 and the enable signal generating unit 145.

At step S108, as with Embodiment 1, the timing constraint file updating unit 114 adds the multicycle path constraint 222 to the timing constraint file 302 to generate the updated timing constraint file 303.

Also, at step S109, as with Embodiment 1, the timing constraint file updating unit 114 outputs the generated updated timing constraint file 303.

At step S402, the enable signal generating unit 145 refers to the multicycle path constraint 222 acquired from the multicycle path constraint generating unit 113, and generates an enable signal. The enable signal generated by the enable signal generating unit 145 is a signal for enabling power gating in a multicycle path period.

If the enable signal concerned has been already present in the RTL data 301, the enable signal generating unit 145 does not generate an enable signal. On the other hand, if the enable signal concerned is not included in the RTL data 301, the enable signal generating unit 145 calculates an output timing of an enable signal, and adds the enable signal to the RTL data 301.

The enable signal generating unit 145 outputs the RTL data 301 added with the enable signal to the power gating description adding unit 117.

At step S403, the power gating description adding unit 117 generates a power gating description based on the RTL data 301 acquired from the enable signal generating unit 145.

The power gating description adding unit 117 generates a power gating description by using, for example, the scheme described in the above-described reference literature (JP 5143061).

Then, at step S404, the power gating description adding unit 117 adds the power gating description to the RTL data 301. Also, the power gating description adding unit 117 outputs the RTL data 301 added with the power gating description as the power gating RTL data 305.

### Description of Effects of Embodiment

In the present embodiment, power gating can be performed between FFs set with the multicycle path and in a period without signal transition.

Thus, compared with Embodiment 3, more reduction in power consumption can be achieved.

In recent years, a RAM with a power gating function has emerged. The RAM with the power gating function has a power return time shorter than that of a normal RAM. Thus, when a RAM is included in a semiconductor integrated circuit as a storage element, if the RAM is replaced by the RAM with the power gating function and an enable signal is connected to a dedicated terminal such as a leak power reducing terminal of the RAM with the power gating function, power gating can be achieved. That is, the semiconductor integrated circuit itself is not required to support power gating.

While Embodiments 1 to 4 have been described above, two or more of these embodiments may be practiced in combination.

Alternatively, one of these embodiments may be practiced in part.

Alternatively, two or more of these embodiments may be practiced in partial combination.

Further, structures and procedures described in these embodiments may be modified as necessary.

### Additional Description on Hardware Structure

Finally, the hardware structure of the multicycle path setting device 100 is additionally described.

The processor 901 depicted in FIG. 3 is an IC (Integrated Circuit) that performs processing.

The processor 901 is a CPU (Central Processing Unit), DSP (Digital Signal Processor), or the like.

The main storage device 902 depicted in FIG. 3 is a RAM (Random Access Memory).

The auxiliary storage device 903 depicted in FIG. 3 is a ROM (Read Only Memory), a flash memory, an HDD (Hard Disk Drive), or the like.

The communication device 904 depicted in FIG. 3 is an electronic circuit that executes communication processing for data.

The communication device 904 is a communication chip or a NIC (Network Interface Card), for example.

The auxiliary storage device 903 also stores an OS (Operating System).

At least a portion of the OS is then executed by the processor 901.

The processor 901 executes the programs implementing the functions of the formal verification executing unit 111 and so forth while executing at least a portion of the OS. The “formal verification executing unit 111 and so forth” refers to the formal verification executing unit 111, the property managing unit 112, the multicycle path constraint generating unit 113, the timing constraint file updating unit 114, the enable signal generating unit 115, the clock gating description adding unit 116, the power gating description adding unit 117, the formal verification executing unit 121, the formal verification executing unit 131, the formal verification executing unit 141, and the enable signal generating unit 145.

Through the execution of the OS by the processor 901, task management, memory management, file management, communication control, and the like are performed.

At least any of information, data, signal values, and variable values indicating the results of processing by the formal verification executing unit 111 and so forth are stored in at least any of the main storage device 902, the auxiliary storage device 903, and a register and a cache memory in the processor 901.

The programs implementing the functions of the formal verification executing unit 111 and so forth may be stored in a portable recording medium such as a magnetic disk, a flexible disk, an optical disk, a compact disk, Blu-ray (registered trademark) disk, and a DVD. Then, the portable recording medium storing the programs implementing the functions of the formal verification executing unit 111 and so forth may be distributed.

Also, at least any “unit” of the formal verification executing unit 111 and so forth may be read as “circuit”, “step”, “procedure”, “process”, or “circuitry”.

Also, the multicycle path setting device 100 may be implemented by a processing circuit. The processing circuit is a logic IC (Integrated Circuit), a GA (Gate Array), an ASIC (Application Specific Integrated Circuit), or an FPGA (Field-Programmable Gate Array), for example.

In this case, the formal verification executing unit 111 and so forth are implemented as portions of the processing circuit.

In the present specification, a superordinate concept of processor and processing circuit is referred to as “processing circuitry”.

That is, processors and processing circuits are each a specific example of “processing circuitry”.

### REFERENCE SIGNS LIST

100: multicycle path setting device; 111: formal verification executing unit; 112: property managing unit; 113: multicycle path constraint generating unit; 114: timing constraint file updating unit; 115: enable signal generating unit; 116: clock gating description adding unit; 117: power gating description adding unit; 121: formal verification executing unit; 131: formal verification executing unit; 141: formal verification executing unit; 145: enable signal generating unit; 211: property; 212: multicycle path constraint; 221: property; 222: multicycle path constraint; 301: RTL data; 302: timing constraint file; 303: updated timing constraint file; 304: clock gating RTL data; 305: power gating RTL data; 901: processor; 902: main storage device; 903: auxiliary storage device; 904: communication device.

1. A data processing device comprising:
processing circuitry
to perform a static analysis of at least either of RTL (Register Transfer Level) data and a net list of a semiconductor integrated circuit having two or more storage elements connected thereto and operating based on a clock cycle, to extract, from the two or more storage elements, a storage element with a shortest time being equal to or more than two clock cycles among times in which no signal transition occurs as a transition pause storage element, and to extract, from the two or more storage elements, a storage element of a connection source of the transition pause storage element as a connection-source storage element; and
to determine to set a multicycle path between the transition pause storage element and the connection-source storage element, wherein
the processing circuitry specifies a clock cycle longer than a power return time when power gating of the semiconductor integrated circuit is performed as a specified clock cycle, extracts a storage element with the shortest time matching the specified clock cycle as the transition pause storage element, and extracts a storage element of a connection source of the transition pause storage element as the connection-source storage element, and
the processing circuitry determines to set a multicycle path corresponding to the specified clock cycle between the transition pause storage element and the connection-source storage element extracted for the specified clock cycle.

2. The data processing device according to claim 1, wherein
the processing circuitry
specifies each of two clock cycles and one or more clock cycles with a value larger than two clock cycles as a specified clock cycle, and
for each specified clock cycle, extracts a storage element with the shortest time matching the specified clock cycle as the transition pause storage element and extracts a storage element of a connection source of the transition pause storage element as the connection-source storage element, and
the processing circuitry determines, for each specified clock cycle, to set a multicycle path corresponding to the specified clock cycle between the transition pause storage element and the connection-source storage element extracted for the specified clock cycle.

3. The data processing device according to claim 2, wherein
the processing circuitry specifies, as the specified clock cycles, two clock cycles and one or more clock cycles with a value larger than two clock cycles by either of a method of increasing the value of the clock cycle sequentially from two clock cycles and a method of decreasing the value of the clock cycle sequentially toward the two clock cycles.

4. The data processing device according to claim 1, wherein
the processing circuitry determines to add a clock gating circuit to perform clock gating in a period of the multicycle path to the semiconductor integrated circuit.

5. The data processing device according to claim 4, wherein
the processing circuitry adds a description of the clock gating circuit to at least either of the RTL data and the net list.

6. The data processing device according to claim 1, wherein
the processing circuitry determines to add a power gating circuit to perform power gating of the semiconductor integrated circuit in a period of the multicycle path to the semiconductor integrated circuit.

7. The data processing device according to claim 6, wherein
the processing circuitry adds a description of the power gating circuit to at least either of the RTL data and the net list.

8. The data processing device according to claim 1, wherein
the processing circuitry performs, as the static analysis, an analysis of at least either of the RTL data and the net list by a formal verification scheme.

9. The data processing device according to claim 1, wherein
the processing circuitry performs the static analysis of at least either of the RTL data and the net list of the semiconductor integrated circuit in which at least either of a FF (Flip-Flop) and a RAM (Random Access Memory) as a storage element is included.

10. A data processing method comprising:
performing a static analysis of at least either of RTL (Register Transfer Level) data and a net list of a semiconductor integrated circuit having two or more storage elements connected thereto and operating based on a clock cycle, extracting, from the two or more storage elements, a storage element with a shortest time being equal to or more than two clock cycles among times in which no signal transition occurs as a transition pause storage element, and extracting, from the two or more storage elements, a storage element of a connection source of the transition pause storage element as a connection-source storage element;
determining to set a multicycle path between the transition pause storage element and the connection-source storage element;
specifying a clock cycle longer than a power return time when power gating of the semiconductor integrated circuit is performed as a specified clock cycle, extracting a storage element with the shortest time matching the specified clock cycle as the transition pause storage element, and extracting a storage element of a connection source of the transition pause storage element as the connection-source storage element; and
setting a multicycle path corresponding to the specified clock cycle between the transition pause storage element and the connection-source storage element extracted for the specified clock cycle.

11. A non-transitory computer readable medium storing a data processing program that causes a computer to execute:
an analyzing and extracting process of performing a static analysis of at least either of RTL (Register Transfer Level) data and a net list of a semiconductor integrated circuit having two or more storage elements connected thereto and operating based on a clock cycle, extracting, from the two or more storage elements, a storage element with a shortest time being equal to or more than two clock cycles among times in which no signal transition occurs as a transition pause storage element, and extracting, from the two or more storage elements, a storage element of a connection source of the transition pause storage element as a connection-source storage element; and
a multicycle path determining process of determining to set a multicycle path between the transition pause storage element and the connection-source storage element, wherein
the analyzing and extracting process specifies a clock cycle longer than a power return time when power gating of the semiconductor integrated circuit is performed as a specified clock cycle, extracts a storage element with the shortest time matching the specified clock cycle as the transition pause storage element, and extracts a storage element of a connection source of the transition pause storage element as the connection-source storage element, and
the multicycle path determining process determines to set a multicycle path corresponding to the specified clock cycle between the transition pause storage element and the connection-source storage element extracted for the specified clock cycle.
